(19) United States
(12) Patent Application Publication
(10) Pub. No.: US 2024/0088265 A1
(43) Pub. Date: Mar. 14, 2024

(54) EPITAXIAL REGIONS EXTENDING BETWEEN INNER GATE SPACERS

(71) Applicant: Intel Corporation, Santa Clara, CA (US)

(72) Inventors: Tao Chu, Portland, OR (US); Guowei Xu, Portland, OR (US); Feng Zhang, Hillsboro, OR (US); Ting-Hsiang Hung, Beaverton, OR (US); Chia-Ching Lin, Portland, OR (US)

(73) Assignee: Intel Corporation, Santa Clara, CA (US)

(21) Appl. No.: 17/940,194

(22) Filed: Sep. 8, 2022

(51) Int. Cl. H01L 29/66; H01L 29/06; H01L 29/786

(52) U.S. Cl. CPC H01L 29/6656; H01L 29/0669; H01L 29/78618

(57) ABSTRACT

Techniques are provided herein to form semiconductor devices having epitaxial growth laterally extending between inner spacer structures to mitigate issues caused by the inner spacer structures either being too thick or too thin. A directional etch is performed along the side of a multilayer fin to create a relatively narrow opening for a source or drain region to increase the usable fin space for forming the inner spacer structures. After the inner spacer structures are formed around ends of the semiconductor layers within the fin, the exposed ends of the semiconductor layers are laterally recessed inwards from the outermost sidewalls of the inner spacer structures. Accordingly, the epitaxial source or drain region is grown from the recessed semiconductor ends and thus fills in the recessed regions between the spacer structures.

### FIELD OF THE DISCLOSURE

The present disclosure relates to integrated circuits, and more particularly, to epitaxial source or drain regions within semiconductor devices.

### BACKGROUND

As integrated circuits continue to scale downward in size, a number of challenges arise. For instance, reducing the size of memory and logic cells is becoming increasingly more difficult. Different transistor architectures that maximize available semiconductor surfaces to form active channels have been contemplated, including nanoribbon (gate-all-around) and forksheet architectures. In such architectures, dielectric barriers, also referred to as inner gate spacers, are formed to provide isolation between transistor gates and source or drain regions. There remain a number of non-trivial challenges with respect to forming such structures.

### BRIEF DESCRIPTION OF THE DRAWINGS

FIG. 1A is a cross-sectional view of a pair of semiconductor devices that illustrates epitaxial growth laterally extending between inner gate spacer structures, in accordance with an embodiment of the present disclosure.

FIG. 1B is a cross-sectional view of a pair of semiconductor devices that illustrates epitaxial growth laterally extending between inner gate spacer structures, in accordance with another embodiment of the present disclosure.

FIGS. 2A-2I′ are cross-section views that illustrate various stages in an example process for forming a semiconductor device having epitaxial growth laterally extending between inner gate spacer structures, in accordance with some embodiments of the present disclosure.

FIG. 3 illustrates a cross-section view of a chip package containing one or more semiconductor dies, in accordance with some embodiments of the present disclosure.

FIG. 4 is a flowchart of a fabrication process for semiconductor devices having epitaxial growth laterally extending between inner gate spacer structures, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices having epitaxial growth that extends between inner gate spacer structures, so as to provide a corrugated-like sidewall profile. Such epitaxial growth may be helpful to mitigate issues caused by the inner gate spacer structures either being too thick or too thin. In an example, a directional etch is performed along the side of a multilayer fin to create a relatively narrow opening for a source or drain region to increase the usable fin space for forming the inner gate spacer structures. After the inner gate spacer structures are formed around ends of the semiconductor layers within the fin, the exposed ends of the semiconductor layers are laterally recessed inwards from the outermost sidewalls of the inner gate spacer structures. Accordingly, the epitaxial source or drain region is grown from the recessed semiconductor ends and thus fills in the recessed regions between the gate spacer structures. Such an example leverages both thicker spacer structures to reduce the chance of causing an electrical short and recessed semiconductor layers to reduce the resistance in the channel layers. Numerous variations and embodiments will be apparent in light of this disclosure.

General Overview

Gate-all-around (GAA) and forksheet device architectures usually have a plurality of semiconductor nanoribbons or nanosheets that extend between a source region and a drain region. As noted above, there are a number of non-trivial issues associated with forming such structures, particularly as dimensions continue to scale downward. For instance, in one example case, a conductive gate electrode is formed around a central portion of the nanoribbons or nanosheets, and is isolated from the source and drain regions via dielectric inner spacer structures, sometimes called inner gate spacers. As devices continue to scale smaller, forming the inner spacer structures has become a challenging task. For example, due to the tapering that occurs when etching the sides of the channel regions when forming the epitaxial source or drain regions, inner spacer structures formed at the bottom of a device tend to be thicker than the inner spacers structures formed at the top of the device. Inner spacers that are too thick result in larger portions of the channel portions being surrounded by the inner spacer, which leads to a higher channel resistance. And inner spacers that are too thin can lead to shorting between the gate electrode and the source or drain region.

Thus, techniques are provided herein to form semiconductor devices with epitaxial growth laterally extending between the inner gate spacers. Such techniques are especially useful for gate all around (GAA) or forksheet transistors that utilize one or more nanoribbons (or nanowires or nanosheets) as the semiconductor channel region between a source and drain region. The term nanoribbons as used herein may refer to any elongated body of semiconductor material extending between source and drain regions (or diffusion regions), such as ribbons, sheets, or wires. The thickness-to-length aspect ratio of such bodies may be relatively low to provide a wider pancake-like body (nanoribbon and nanosheet) that extends between source and drain regions, or relatively higher to provide a less flat and narrower body (nanowire) that extends between source and drain regions. The inner spacers are provided to isolate the gate electrode over the channel region from the source or drain regions. The source or drain regions extend between portions of the inner spacers due to the ends of the nanoribbons (or other channel bodies) being recessed back from the outermost sidewalls of the inner spacers. The recessed nanoribbons allow for thicker inner spacers to be used (better for protecting against shorts) without causing a significant reduction in the channel resistance of the resulting device. Numerous variations and embodiments will be apparent in light of this disclosure.

According to an embodiment, an integrated circuit includes a semiconductor device having a plurality of semiconductor nanoribbons extending lengthwise in a first direction between a first epitaxial region and a second epitaxial region and being over one another in a second direction. In addition, a spacer structure extends in the second direction around ends of the semiconductor nanoribbons, and a gate structure at least partially around a channel region of the plurality of semiconductor nanoribbons. The end of a given semiconductor nanoribbon is laterally recessed inward from an outermost sidewall of an adjacent portion of the spacer structure. While nanoribbons are used in this example, other channel bodies may be used as well (such as nanosheets or nanowires), wherein the end of a given semiconductor channel body is laterally recessed inward from an outermost sidewall of an adjacent portion of the spacer structure. The gate structure may be, for example, a gate-all-around structure, or a forksheet transistor device.

According to another embodiment, an integrated circuit includes a semiconductor device having a plurality of semiconductor nanoribbons extending lengthwise in a first direction from a first epitaxial region to a second epitaxial region and being over one another in a second direction, a first spacer structure that extends in the second direction around first ends of the semiconductor nanoribbons adjacent to the first epitaxial region, a second spacer structure that extends in the second direction around second ends of the semiconductor nanoribbons adjacent to the second epitaxial region, and a gate structure around the plurality of semiconductor nanoribbons and between the first spacer structure and the second spacer structure. First portions of the first epitaxial region extend laterally in the first direction within the first spacer structure to contact the first ends of the semiconductor nanoribbons, and second portions of the second epitaxial region extend laterally in a third direction opposite to the first direction within the second spacer structure to contact the second ends of the semiconductor nanoribbons. In this manner, each of the first and second epitaxial regions includes a gate-facing sidewall that has a corrugated-like appearance in cross-sectional profile. In particular, portions of a given epitaxial region's gate-facing sidewall laterally adjacent to the nanoribbons laterally extend outward from that epitaxial region further than portions of the gate-facing sidewall laterally adjacent to the corresponding spacer structure.

According to another embodiment, a method of forming an integrated circuit includes forming a multilayer fin extending lengthwise in a first direction, the multilayer fin including first material layers alternating with second material layers, the second material layers comprising a semiconductor material suitable for use as a channel region (e.g., nanoribbon or nanosheet); forming a sacrificial layer and spacers on sidewalls of the sacrificial layer, the sacrificial layer and spacers extending over the multilayer fin in a second direction different form (e.g., orthogonal to) the first direction; removing portions of the multilayer fin not protected beneath the sacrificial layer and spacers; laterally etching exposed ends of the first material layers; forming an internal spacer around exposed ends of the second material layers; laterally etching the exposed ends of the second material layers, such that the ends of the second material layers are laterally recessed inward from an outermost sidewall of the inner spacer; and growing an epitaxial material from the ends of the second material layers.

The techniques can be used with any type of non-planar transistors, but are especially useful for nanoribbon or nanosheet transistors (sometimes called GAA transistors or forksheet transistors, respectively), to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate thicker than usual inner spacers (e.g., 20%-50% thicker). In some examples, the epitaxial source or drain regions can be observed in a cross-sectional profile as extending laterally within the inner spacer to contact a laterally recessed end of one or more nanoribbons or other channel bodies, or as having a gate-facing sidewall having a corrugated-like appearance.

It should be readily understood that the meaning of “above” and “over” in the present disclosure should be interpreted in the broadest manner such that “above” and “over” not only mean “directly on” something but also include the meaning of over something with an intermediate feature or a layer therebetween. As used herein, the term “backside” generally refers to the area beneath one or more semiconductor devices (below the device layer) either within the device substrate or in the region of the device substrate (in the case where the bulk of the device substrate has been removed). Note that the backside may become a frontside, and vice-versa, if a given structure is flipped. To this end, and as will be appreciated, the use of terms like “above” “below” “beneath” “upper” “lower” “top” and “bottom” are used to facilitate discussion and are not intended to implicate a rigid structure or fixed orientation; rather such terms merely indicate spatial relationships when the structure is in a given orientation.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Architecture

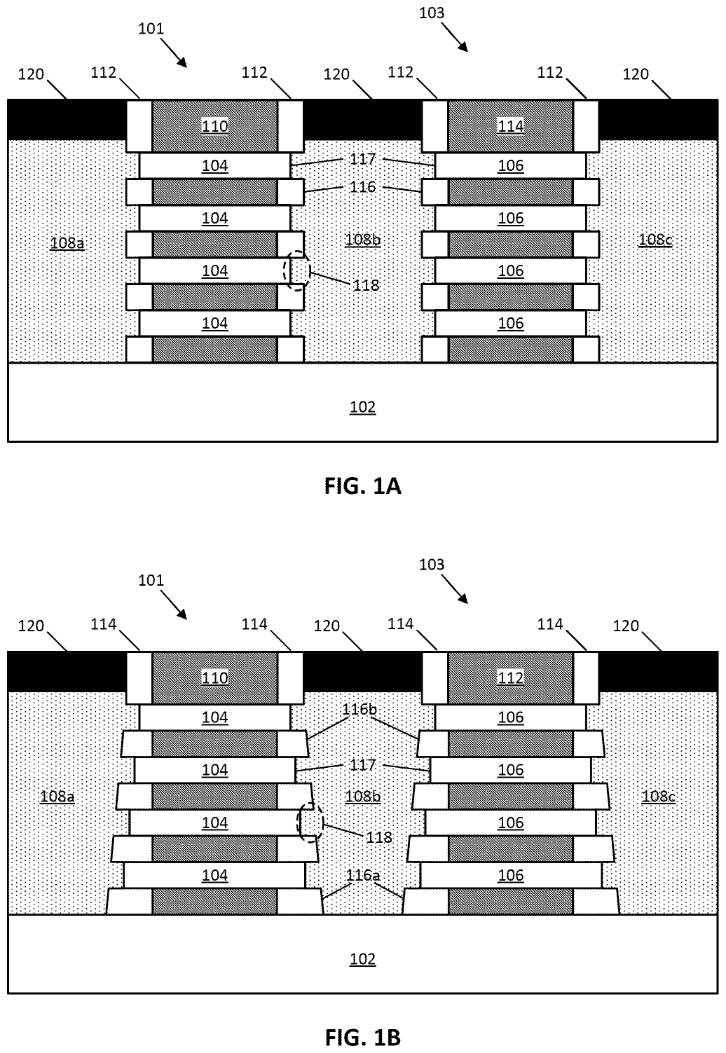

FIG. 1A is a cross-sectional view taken across a first semiconductor device 101 and a second semiconductor device 103, according to an embodiment of the present disclosure. Each of first and second semiconductor devices 101 and 103 may be any type of non-planar metal oxide semiconductor (MOS) transistor, such as gate-all-around (GAA), or forksheet transistor, although other transistor topologies and types could also benefit from the techniques provided herein. The illustrated embodiments herein use the GAA structure, but they are equally applicable to a forksheet structure.

First and second semiconductor devices 101 and 103 together represent a portion of an integrated circuit that may contain any number of similar semiconductor devices. Additionally, first and second semiconductor devices 101 and 103 are provided side-by-side for clarity and for ease of discussion when comparing and contrasting the devices. However, second semiconductor device 103 could exist anywhere else within the integrated circuit and is not required to be linked with first semiconductor device 101 via a shared source or drain region. The arrangement of first semiconductor device 101 sharing a source or drain region with second semiconductor device 103 may be used in various common circuit structures, such as an inverter.

As can be seen, semiconductor devices 101 and 103 are formed on a substrate 102. Any number of other semiconductor devices can be formed on substrate 102, but two are illustrated here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of (or all of) substrate 102 is removed and replaced with one or more backside interconnect layers to form backside signal and power routing.

First semiconductor device 101 may include any number of semiconductor nanoribbons 104 while second semiconductor device 103 similarly may include any number of semiconductor nanoribbons 106. Nanoribbons 104 may extend between a source or drain region 108a and a source or drain region 108b. Likewise, nanoribbons 106 may extend between source or drain region 108b and source or drain region 108c. Any source region may also act as a drain region and vice versa, depending on the application.

In some embodiments, semiconductor devices 101 and 103 have an equal number of nanoribbons, while in other embodiments they have an unequal number of nanoribbons. In some embodiments, each of nanoribbons 104 and nanoribbons 106 are formed from a fin of alternating material layers (e.g., alternating layers of silicon and silicon germanium) where sacrificial material layers are removed between nanoribbons 104 and nanoribbons 106. Each of nanoribbons 104 and nanoribbons 106 may include the same semiconductor material as substrate 102, or not, and may be doped, or not. According to some embodiments, semiconductor device 101 is a p-channel device having semiconductor nanoribbons 104 doped with n-type dopants (e.g., phosphorous or arsenic) and semiconductor device 103 is an n-channel device having semiconductor nanoribbons 106 doped with p-type dopants (e.g., boron).

According to some embodiments, source or drain regions 108a-108c are epitaxial regions that are provided using an etch-and-replace process. Any semiconductor materials suitable for source or drain regions can be used (e.g., group IV and group III-V semiconductor materials). Source or drain regions 108a-108c may include multiple layers such as liners and capping layers to improve contact resistance. In any such cases, the composition and doping of source or drain regions 108a-108c may be the same or different, depending on the polarity of the transistors. Any number of source and drain configurations and materials can be used.

According to some embodiments, the fins or semiconductor material can be formed of material deposited over the underlying substrate 102. In one such example case, a blanket layer of silicon germanium (SiGe) can be deposited over a silicon substrate, and then patterned and etched to form a plurality of SiGe fins or nanoribbons. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins or deposited into fin-shaped trenches.

According to some embodiments, a first gate structure 110 is provided over each of nanoribbons 104 between spacer structures 112 and inner spacers 116. Similarly, a second gate structure 114 is provided over each of nanoribbons 106 between spacer structures 112 and inner spacers 116. Each of first and second gate structures 110 and 114 include both a gate dielectric (not shown) around the corresponding nanoribbons and a gate electrode over the gate dielectric. The gate dielectric may also be deposited along sidewalls and the bottom of the trench between spacer structures 112 and inner spacers 116. The gate dielectric may include a single material layer or multiple stacked material layers. In some embodiments, the gate dielectric includes a first dielectric layer such as silicon oxide and a second dielectric layer that includes a high-k material such as hafnium oxide. The hafnium oxide may be doped with an element to affect the threshold voltage of the given semiconductor device. According to some embodiments, a doping element is used in the gate dielectric, such as lanthanum.

According to some embodiments, first and second gate structures 110 and 114 include a gate electrode that extends over the gate dielectric around each of nanoribbons 104 and 106, respectively. The gate electrode may include any sufficiently conductive material such as a metal (e.g., tungsten), metal alloy, or doped polysilicon. According to some embodiments, the gate electrode may be interrupted between any other semiconductor devices by a gate cut structure. In some embodiments, the gate electrode includes one or more workfunction metals around the corresponding nanoribbons. For example, first semiconductor device 101 may be a p-channel device that includes a workfunction metal having titanium around nanoribbons 104. In another example, second semiconductor device 103 is an n-channel device that includes a workfunction metal having tungsten around nanoribbons 106. In some embodiments, first and second gate electrodes 110 and 114 each includes a fill metal or other conductive material around the workfunction metal(s) to provide the whole gate electrode structure.

According to some embodiments, the ends 117 of nanoribbons 104 and 106 are laterally recessed inwards (e.g., towards their respective gate structures) and away from an outermost sidewall of inner spacers 116. In some embodiments, the ends 117 of nanoribbons 104 and 106 are laterally recessed by 5 angstroms or more, such as between 1 nm and 5 nm, or between 2 nm and 3 nm, from the outermost sidewall of inner spacers 116. Since ends 117 of nanoribbons 104 and 106 are recessed in this way, source or drain regions 108a-108c extend into the recesses between adjacent (upper and lower) portions of inner spacers 116. These protruding portions 118 of source or drain regions 108a-108c extend into at least a portion of the lateral thickness of inner spacers 116. According to some example embodiments, inner spacers 116 have a lateral thickness between about 5 nm and about 10 nm.

Due to limitations imposed during etching processes, the source or drain regions 108a-108c along the sides of the nanowires 104/106 may taper inwards as illustrated in FIG. 1B. This tapering respectively causes inner spacers 116 to have a tapered lateral thickness along a height of the device, such that a lowest inner spacer 116a has a greater lateral thickness compared to a highest inner spacer 116b (e.g., 1 nm or more greater). In some embodiments, lowest inner spacer 116a has a lateral thickness between about 6 nm and about 10 nm or between about 7 nm and about 8 nm, and highest inner spacer 116b has a lateral thickness between about 3 nm and about 5 nm. The protruding portions 118 of source or drain regions 108a-108c may have substantially the same (e.g., within 1-2 nm) lateral thickness along the height of the device. Accordingly, nanoribbons 104 and 106 may have lengths that taper along the height of the devices such that a highest nanoribbon 104/106 has a smaller length than a lowest nanoribbon 104/106. Since the sidewalls of inner spacers 116 may be tapered as illustrated, the end 117 of a given nanoribbon is considered to be recessed with respect to the outermost sidewalls of the directly adjacent portions of inner spacers 116 (either directly above, directly below, or directly above and below). In any case, the recessed ends 117 of nanoribbons 104 and 106 reduce the amount of undoped channel between inner spacers 116 thus lowering the resistance of the device, and the thicker inner spacers 116 reduce the chance of shorting between gate structures 110/112 and source or drain regions 108a-108c.

The protruding portions 118 may be thought of as being offset from, or otherwise contrasted with, indented portions of source or drain regions 108a-108c into which the internal spacers seemingly extend, as shown in the cross-sectional views of FIGS. 1A-B. In this manner, each of the source or drain regions 108a-108c includes a gate-facing sidewall that has a corrugated-like appearance in cross-sectional profile. In particular, portions of a given epitaxial region's 108a-108c gate-facing sidewall laterally adjacent to channel bodies 104 or 106 laterally extend outward from that epitaxial region 108a-108c further than portions of the gate-facing sidewall laterally adjacent to a corresponding spacer structure 116. As shown in FIG. 1A, the corrugated sidewall may be relatively straight (vertical), such that the sidewalls of the indented portions are substantially colinear with each other and the sidewalls of the protrusions are substantially colinear with each other. In the alternative embodiment shown in FIG. 1B, the corrugated sidewalls of source/drain regions 108a-c may taper inward or otherwise be angled, such that the lower indents are further inward than the upper indents, and the lower protrusions are further inward than the upper protrusions.

A conductive contact 120 may be formed over each of source or drain regions 108a-108c to provide electrical connections to each of source or drain regions 108a-108c. Conductive contact 120 can include any suitable conductive material, such as tungsten, copper, cobalt, titanium, ruthenium, or tantalum.

Fabrication Methodology

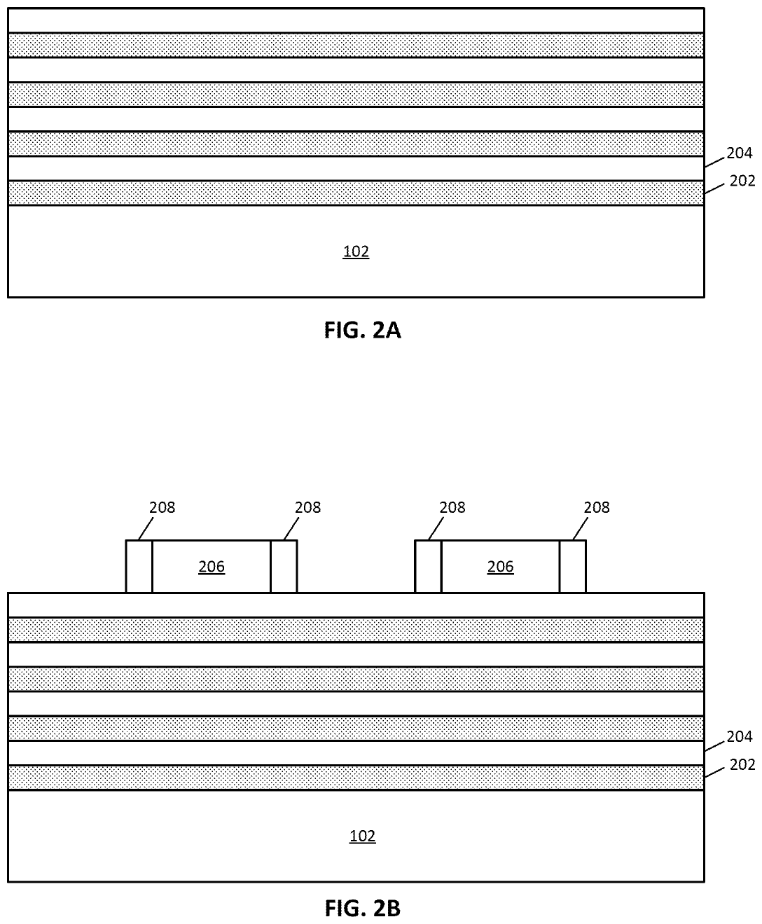

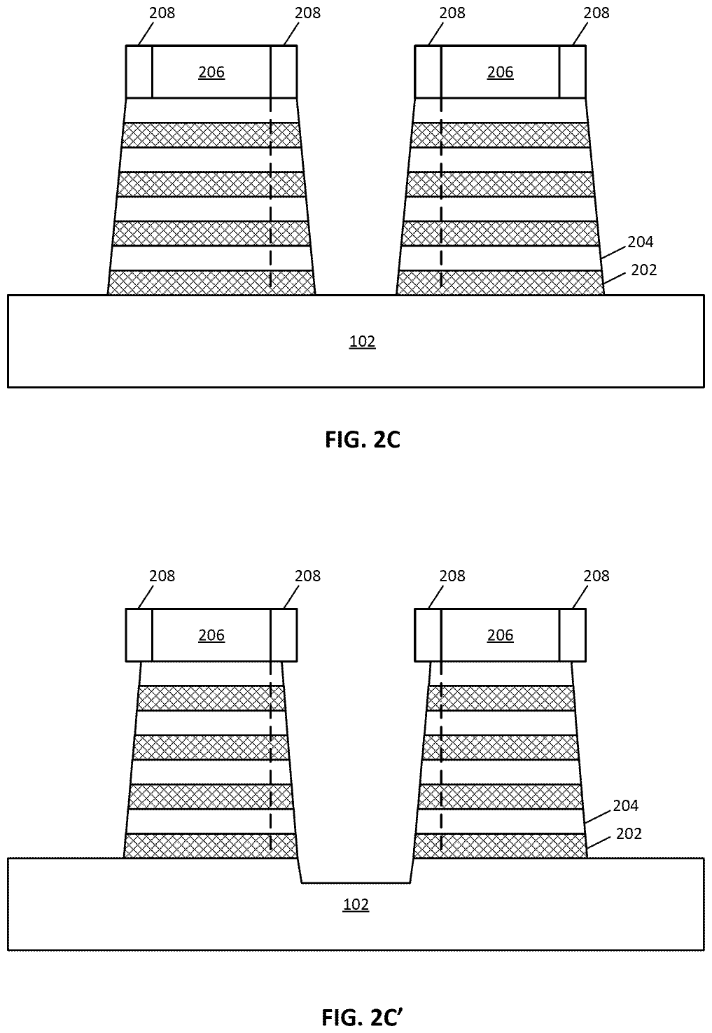

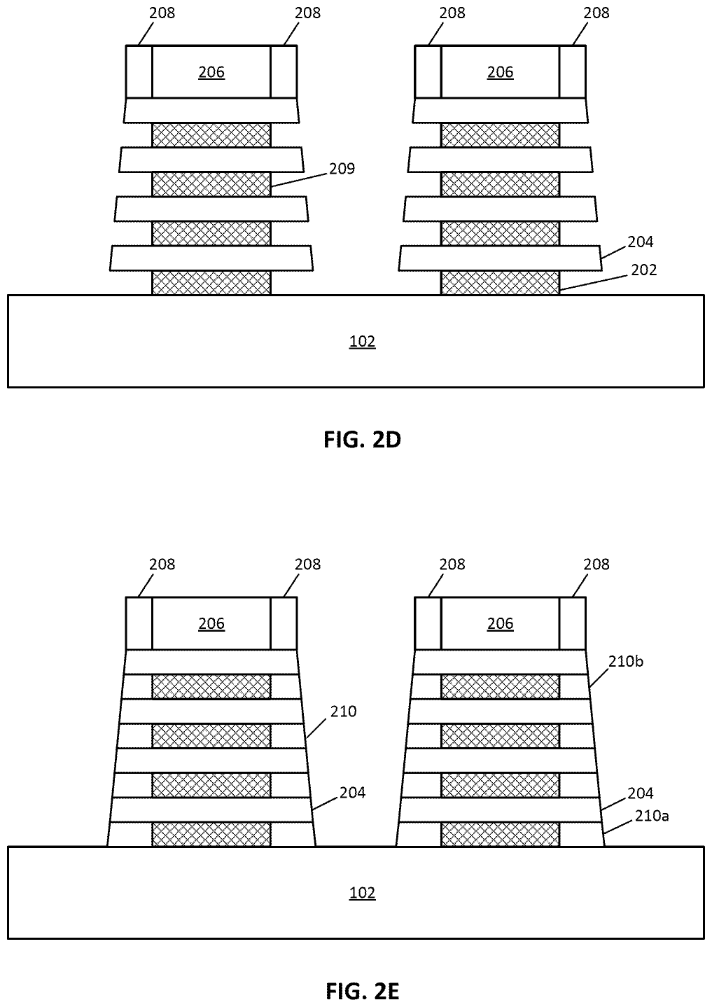

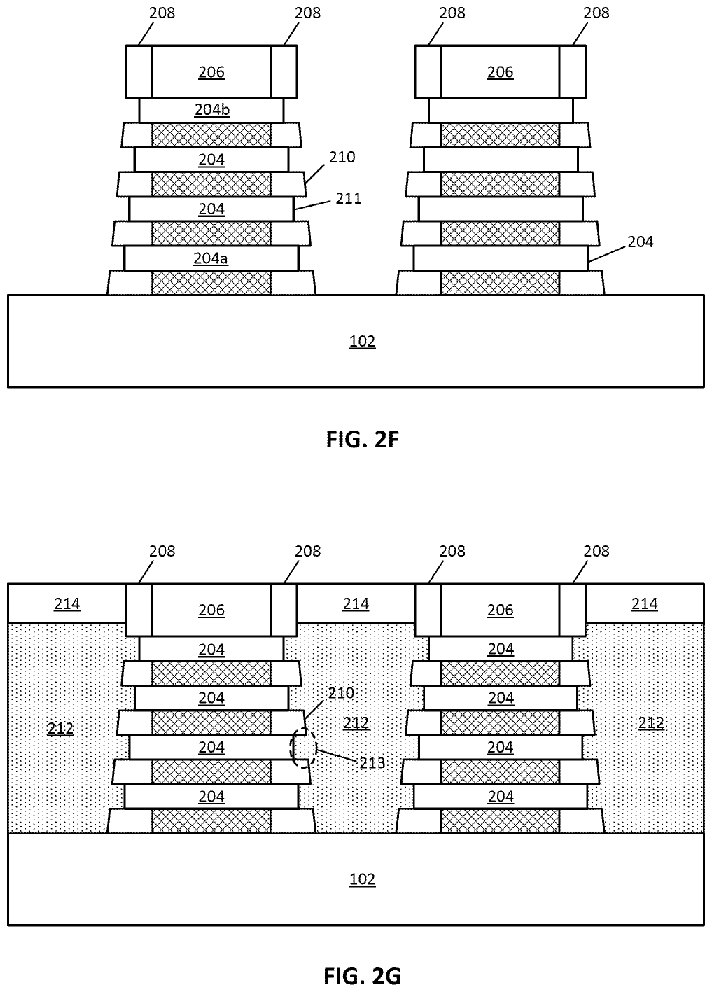

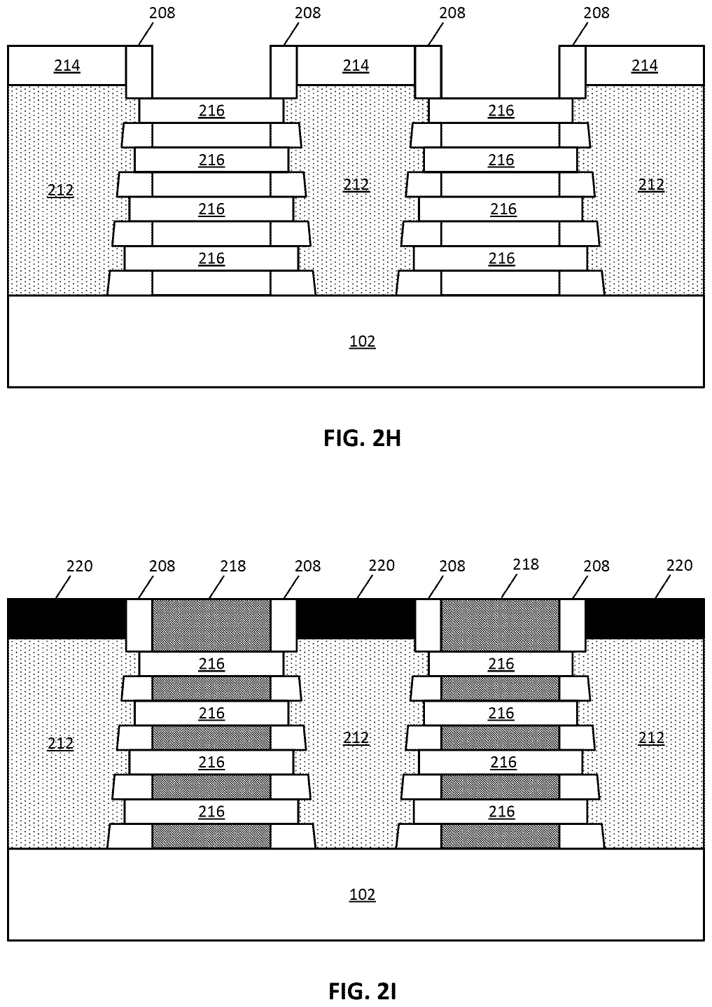

FIGS. 2A-2I′ include cross-sectional views that collectively illustrate an example process for forming an integrated circuit configured with semiconductor devices having source or drain regions configured with a cross-sectional sidewall profile that includes alternating indents and protrusions, so as to provide a corrugated-like appearance, according to some embodiments. Each figure shows an example structure that results from the process flow up to that point in time, so the depicted structure evolves as the process flow continues, culminating in the structure shown in FIG. 2I, which is similar to the structure shown in FIG. 1B. The illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 2A illustrates substrate 102 having a series of material layers formed over the substrate, according to an embodiment of the present disclosure. Alternating material layers may be deposited over substrate 102 including sacrificial layers 202 alternating with semiconductor layers 204. Any number of alternating semiconductor layers 204 and sacrificial layers 202 may be deposited over substrate 102. It should be noted that the cross section illustrated in FIG. 2A is taken along the length of a fin formed from the multiple layers and extending up above the surface of substrate 102.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204. Semiconductor layers 204 may be doped with either n-type dopants (to produce a p-channel transistor) or p-type dopants (to produce an n-channel transistor).

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known material deposition technique, such as chemical vapor deposition (CVD), plasma-enhanced chemical vapor deposition (PECVD), physical vapor deposition (PVD), or atomic layer deposition (ALD).

FIG. 2B illustrates a cross-sectional view of the structure shown in FIG. 2A following the formation of sacrificial gate structures 206 and spacer structures 208 over the alternating layer structure of the fin, according to an embodiment. Sacrificial gate structures 206 may run in an orthogonal direction to the length of the fin and may include any material that can be safely removed later in the process without etching or otherwise damaging any portions of the fin or of spacer structures 208. In some embodiments, sacrificial gate structures 206 include polysilicon. Spacer structures 208 may be formed using an etch-back process where spacer material is deposited everywhere and then anisotropically etched to leave the material only on sidewalls of structures including sacrificial gate structures 206. Spacer structures 208 may include a dielectric material, such as silicon nitride, silicon oxy-nitride, or any formulation of those layers incorporating carbon or boron dopants. Sacrificial gate structures 206 together with spacer structures 208 define portions of the fin that will be used to form source and drain regions of the first and second semiconductor devices, as discussed further herein.

FIG. 2C illustrates a cross-sectional view of the structure shown in FIG. 2B following the removal of the exposed fin not under sacrificial gate structures 206 and spacer structures 208, according to an embodiment of the present disclosure. According to some embodiments, the various alternating material layers are etched in a directional fashion (downward) at substantially the same rate using an anisotropic reactive ion etching (RIE) process. The RIE process may also etch into substrate 102 thus recessing portions of substrate 102 on either side of any of the fins. The geometry of the source/drain opening being formed may vary from one example to the next, but in some case are relatively narrow and deep, such as recesses having a 2:1 or higher height-to-width aspect ratio (e.g., 3:1, 4:1, 5:1, 8:1). In some examples, the width (distance from left edge to right edge at top of opening) of the trench opening can be smaller than the width of the neighboring fins (distance from leftmost outer edge of leftmost spacer 208 to rightmost outer edge of second-to-left spacer 208), such that the ratio of gate width to opening width is in the range of 1:0.9 or smaller (e.g., 1:0.67, 1:0.5, 1:0.33, 1:0.25). In some examples, the width at the top of the fins (under spacers 208) is in the range of 40 to 80 nm and the width of the opening is in the range of 15 to 30 nm. The depth of the opening in some such examples may be in the range of 50 nm to 150 nm. More generally, the techniques provided herein can be readily used with any geometry scheme for the openings and gate structures 208.

According to some embodiments, the etching process naturally tapers inwards as the etch continues deeper through the alternating layer stack of sacrificial layers 202 and semiconductor layers 204. The etch chemistry and timing may be controlled to minimize or otherwise reduce undercutting of the alternating layers stack beneath spacer structures 208. FIG. 2C′ illustrates an example of an etch that has proceeded for too long and has thus undercut the layer stack beneath spacer structures 208. A narrower or shallower etch as illustrated in FIG. 2C provides a greater amount of lateral space with which to form inner spacer structures. The etching process used to cut through the layer stack in FIG. 2C may be considered to be shallower because it does not extend as deep into substrate 102 compared to the etching process used to cut through the layer stack in FIG. 2C′. According to some embodiments, a greater portion of the fin exists between the dashed line and the now tapered sidewall of the fin in the structure of FIG. 2C when compared to the structure of FIG. 2C′, due to the controlled etching process that minimizes or otherwise reduces undercutting beneath spacer structures 208. The longer (from left to right) fins in the structure of FIG. 2C allow for inner spacers to be formed with a greater lateral thickness, without the inner spacers extending past the dashed line into the channel region (as the spacers would otherwise impede on the channel region and later-formed gate structures).

FIG. 2D illustrates a cross-sectional view of the structure shown in FIG. 2C following the removal of portions of sacrificial layers 202, according to an embodiment of the present disclosure. An isotropic etching process may be used to recess the exposed ends of each of sacrificial layers 202 while not etching (or etching relatively little of) semiconductor layers 204. According to some embodiments, sacrificial layers 202 are recessed such that the ends 209 of sacrificial layers 202 are substantially aligned with the boundary between sacrificial gate 206 and spacer structure 208. Due to the tapered sidewalls of the fin, the etching of sacrificial layers 202 may leave a larger recess at the bottom of the fin as compared to the top of the fin.

FIG. 2E illustrates a cross-sectional view of the structure shown in FIG. 2D following the formation of inner spacers 210, according to an embodiment of the present disclosure. Inner spacers 210 may have a material composition that is similar to or the exact same as spacer structures 208. Accordingly, inner spacers 210 may be any suitable dielectric material that exhibits high etch selectively to semiconductor materials such as silicon and/or silicon germanium. Inner spacers 210 may be conformally deposited over the sidewalls of the fin structure using a CVD process like ALD and then etched back using an isotropic etching process to expose the ends of semiconductor layers 204.

According to some embodiments, the outermost sidewalls of inner spacers 210 follow the tapered angle of the ends of semiconductor layers 204. Thus, the bottommost inner spacers 210a may have a greater lateral thickness compared to the topmost inner spacers 210b with the lateral thickness gradually changing for portions of inner spacers 210 between the bottommost inner spacers 210a and the topmost inner spacers 210b. As noted above, bottommost inner spacer 210a has a lateral thickness between about 6 nm and about 10 nm or between about 7 nm and about 8 nm and topmost inner spacer 210b has a lateral thickness between about 3 nm and about 5 nm, according to some embodiments.

FIG. 2F illustrates a cross-sectional view of the structure shown in FIG. 2E following the recessing of the ends 211 of semiconductor layers 204, according to some embodiments. An isotropic etching process may be used to recess the exposed ends of each of semiconductor layers 204 while not etching (or etching relatively little of) inner spacers 210. Semiconductor layers 204 may be recessed by between about 1 nm and about 5 nm, or between about 2 nm and about 3 nm from the outermost sidewalls of inner spacers 210. Since the sidewalls of inner spacers 210 are tapered, the end 211 of a given nanoribbon is considered to be recessed with respect to the outermost sidewalls of the directly adjacent portions of inner spacers 210 (either directly above, directly below, or directly above and below).

According to some embodiments, each semiconductor layer 204 of a given fin is recessed by substantially the same amount, which leads to semiconductor layers 204 of different lengths. For example, a bottom-most semiconductor layer 204a may be between 3 nm and 5 nm longer than a top-most semiconductor layer 204b.

FIG. 2G illustrates a cross-sectional view of the structure shown in FIG. 2F following the formation of source or drain regions 212, according to an embodiment of the present disclosure. As noted above, any of source or drain regions 212 can act as either a source or drain depending on the application. In some examples, source or drain regions 212 are epitaxially grown from the ends of semiconductor layers 204. Any semiconductor materials suitable for source or drain regions 212 can be used (e.g., group IV and group III-V semiconductor materials). Source or drain regions 212 may include multiple layers such as liners and capping layers to improve contact resistance. In any such cases, the composition and doping of source or drain regions 212 may be the same or different, depending on the polarity of the transistors. Any number of source or drain configurations and materials can be used. According to some embodiments, source or drain regions 212 include protruding portions 213 that extend into inner spacers 210 and contact the ends of semiconductor layers 204.

A dielectric cap layer 214 may be formed over one or more of source or drain regions 212, according to some embodiments. Dielectric cap layer 214 allows for a planarized structure, such that the top surface of sacrificial gate 206 is co-planar with the top surface of dielectric cap layer 214. Dielectric cap layer 214 may be any suitable dielectric material, such as silicon oxide, aluminum oxide, silicon nitride, or silicon oxycarbonitride.

FIG. 2H illustrates a cross-sectional view of the structure shown in FIG. 2G following the removal of the sacrificial gate 206 and sacrificial layers 202, according to an embodiment of the present disclosure. The sacrificial gate 206 may be removed using any wet or dry isotropic process thus exposing the alternating layer stack of the fin within the trench left behind after the removal of sacrificial gate 206. Once sacrificial gate 206 has been removed, the exposed sacrificial layers 202 may also be removed using a selective isotropic etching process that removes the material of sacrificial layers 202 but does not remove (or removes very little of) semiconductor layers 204. At this point, the suspended semiconductor layers 204 form nanoribbons 216 (or nanowires or nanosheets) that extend between source or drain regions 212.

FIG. 2I illustrates a cross-sectional view of the structure shown in FIG. 2H following the formation of gate structures 218 around the suspended nanoribbons 216, according to an embodiment of the present disclosure. As noted above, gate structures 218 include a gate dielectric and a gate electrode.

The gate dielectric may be conformally deposited around nanoribbons 216 using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on nanoribbons 216, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-k material can be nitridized to improve its aging resistance.

The gate electrode may be deposited over the gate dielectric and can be any standard or proprietary conductive material that may include any number of gate cuts. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. In one example, a semiconductor device is a PMOS device and the workfunction layers include, for example, p-type workfunction materials (e.g., titanium nitride). In the case of an NMOS device, n-type workfunction materials can include titanium aluminum carbide.

According to some embodiments, all of (or at least a portion of) dielectric cap layers 214 are removed and replaced with contacts 220. Contacts 220 may be any suitable conductive material for making electrical contact with the underlying source or drain regions 212. In some embodiments, contacts 220 include tungsten, copper, cobalt, titanium, ruthenium, or tantalum.

As discussed above, the various nanoribbons 216 of a given device may have different lengths due to the lateral etching process across a tapered sidewall fin profile. However, controlled etches may also be performed to etch the ends of the semiconductor layers 204 such that the ends are substantially aligned with one another along a vertical direction. FIG. 2I′ illustrates an example cross-section of an integrated circuit that is similar to FIG. 2I, but with nanoribbons 216 that are substantially the same length (within 1-2 nm) in a given device. Inner spacers 210 may continue to exhibit a tapering lateral thickness along the height of the device. In any case, the recessed ends of nanoribbons 216 reduce the amount of undoped channel between inner spacers 210 thus lowering the resistance of the devices, and the thicker inner spacers 210 reduce the chance of shorting between gate structures 218 and source or drain regions 212.

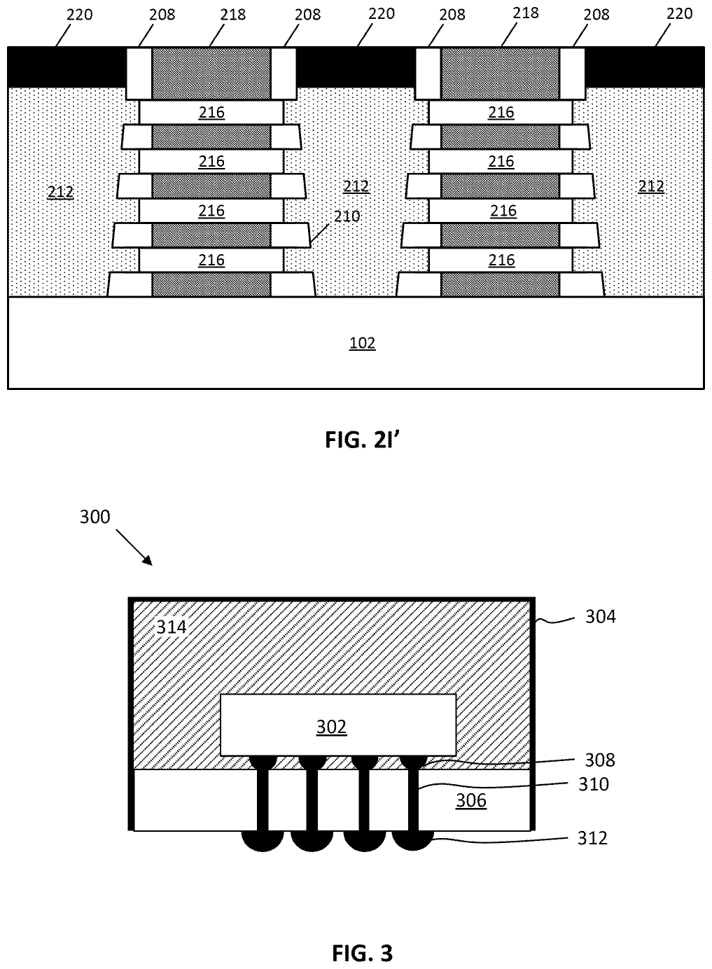

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

Methodology

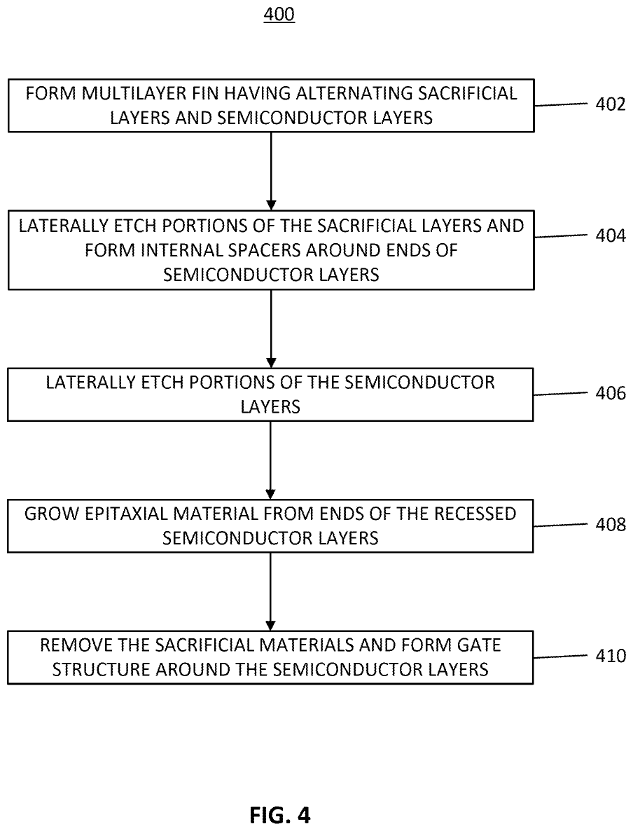

FIG. 4 is a flow chart of a method 400 for forming at least a portion of an integrated circuit, according to an embodiment. Various operations of method 400 may be illustrated in FIGS. 2A-2I′. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. Some of the operations of method 400 may be performed in a different order than the illustrated order.

Method 400 begins with operation 402 where a multilayer fin is formed having alternating semiconductor and sacrificial layers. The sacrificial layers may include SiGe while the semiconductor layers may be Si, SiGe, Ge, InP, or GaAs, to name a few examples. The thickness of each of the sacrificial and semiconductor layers may be between about 5 nm and about 20 nm or between about 5 nm and about 10 nm. Each of the sacrificial and semiconductor layers may be deposited using any known material deposition technique, such as CVD, PECVD, PVD, or ALD. The fin of alternating material layers may be defined by patterning a sacrificial gate and spacer structures that extend orthogonally over the fin, then etching around the sacrificial gate and spacer structures via an anisotropic etching process, such as RIE.

The RIE process used to form the fin beneath the sacrificial gate and spacer structures may form tapered fin sidewalls. According to some embodiments, the etch is timed so as to limit the amount of undercutting that occurs beneath the spacer structures and maximize the width at the top of the fin and the width at the bottom of the fin (as the bottom fin width will be wider due to the tapering etch profile).

Method 400 continues with operation 404 where the sacrificial layers of the fin are laterally etched and inner spacers are formed around the ends of the semiconductor layers. The sacrificial layers may be laterally etched back using an isotropic etching process while the inner spacers fill the recesses between the semiconductor layers. The inner spacers may have a material composition that is similar to or the exact same as the spacer structures on either side of the sacrificial gate. Accordingly, the inner spacers may be any suitable dielectric material that exhibits high etch selectively to semiconductor materials such as silicon and/or silicon germanium. The inner spacers may be conformally deposited over the sides of the fin structure using a CVD process like ALD and then etched back using an isotropic etching process to expose the ends of the semiconductor layers. Due to the tapered profile of the fin, a bottommost inner spacer may have a greater lateral thickness than a topmost inner spacer.

Method 400 continues with operation 406 where the exposed ends of the semiconductor layers are laterally etched. An isotropic etching process may be used to recess the exposed ends of each of the semiconductor layers while not etching (or etching relatively little of) the inner spacers. The semiconductor layers may be recessed by between about 1 nm and about 5 nm, or between about 2 nm and about 3 nm from the outermost sidewalls of the inner spacers. Since the sidewalls of the inner spacers may be tapered, the end of a given nanoribbon is considered to be recessed with respect to the outermost sidewalls of the directly adjacent portions of the sidewall spacers (either directly above, directly below, or directly above and below).

Method 400 continues with operation 408 where epitaxial source or drain regions are formed from the recessed ends of the semiconductor layers. According to some embodiments, the source or drain regions begin growing from the exposed ends of the semiconductor layers and merge together to form the entirety of the regions along the sides of the fin. Any semiconductor materials suitable for source or drain regions can be used (e.g., group IV and group III-V semiconductor materials). According to some embodiments, since the ends of the semiconductor layers have been recessed from the ends of the inner spacers, the source or drain regions will seemingly have protruding portions that extend within the inner spacers and contact the ends of the semiconductor layers. Likewise, the source or drain regions will seemingly have indented portions into which the inner spacers extend.

Method 400 continues with operation 410 where the various sacrificial materials (including the sacrificial gate and the sacrificial layers) are removed and are replaced with a gate structure around the suspended semiconductor layers (e.g., nanoribbons) that extend between the source or drain regions. One or more isotropic etching procedures may be performed to remove the sacrificial gate and sacrificial layers.

The gate structure may include both a gate dielectric and a gate electrode. The gate dielectric is first formed over the suspended nanoribbons between the spacer structures followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

Example System

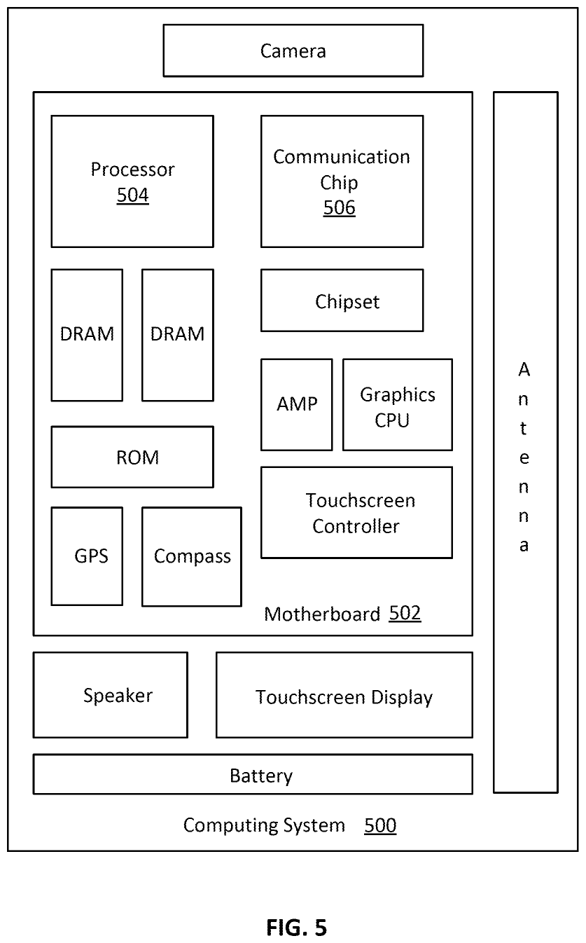

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment (e.g., a module including an integrated circuit on a substrate, the substrate having semiconductor devices with source or drain regions having a corrugated like sidewall profile where portions of the source or drain regions laterally extend into the inner gate spacer structure, as variously provided herein). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor body and a second semiconductor body each extending lengthwise in a first direction between a first epitaxial region and a second epitaxial region with the first semiconductor body over the second semiconductor body in a second direction, a gate structure at least partially around the first and second semiconductor bodies, and a spacer structure that extends in the second direction around ends of the first and second semiconductor bodies. The end sidewall of a given semiconductor body is laterally inward of an outermost sidewall of an adjacent portion of the spacer structure.

Example 2 includes the integrated circuit of Example 1, wherein the first and second semiconductor bodies are nanoribbons that comprise germanium, silicon, or any combination thereof.

Example 3 includes the integrated circuit of Example 1 or 2, wherein at least one of the first or second epitaxial regions has a protruding portion and an indented portion, the protruding portion laterally extending toward the gate structure and between upper and lower portions of the spacer structure, and the indented portion having a portion of the spacer structure extending therein.

Example 4 includes the integrated circuit of any one of Examples 1-3, wherein at least one of the first or second epitaxial regions has a sidewall facing the gate structure, and that sidewall has a corrugated appearance in cross-section, the corrugated appearance including protruding epitaxial regions that extend into the spacer structure and second indented epitaxial regions that receive a corresponding portion of the spacer structure.

Example 5 includes the integrated circuit of any one of Examples 1-4, wherein the spacer structure is a first spacer structure on one side of the gate structure, and the integrated circuit further comprises a second spacer structure on an opposite side of the gate structure, the second spacer structure extending in the second direction around opposite ends of the first and second semiconductor bodies.

Example 6 includes the integrated circuit of Example 5, wherein the opposite ends of the first and second semiconductor bodies are laterally inward from an outermost sidewall of the second spacer structure.

Example 7 includes the integrated circuit of any one of Examples 1-6, wherein the second direction is orthogonal to the first direction.

Example 8 includes the integrated circuit of any one of Examples 1-7, wherein the recessed ends of the first and second semiconductor bodies are substantially aligned along the second direction.

Example 9 includes the integrated circuit of any one of Examples 1-8, wherein portions of the first epitaxial region contact the ends of the first and second semiconductor bodies, such that the spacer structure extends in the second direction around the portions of the first epitaxial region.

Example 10 includes the integrated circuit of any one of Examples 1-9, wherein the spacer structure between adjacent ends of the first and second semiconductor bodies has a lateral thickness in the first direction of between 5 nm and 10 nm.

Example 11 includes the integrated circuit of any one of Examples 1-10, wherein an uppermost portion of the spacer structure has a first lateral thickness in the first direction and a lowermost portion of the spacer structure has a second lateral thickness in the first direction, the second lateral thickness being 1 nm or more greater than the first lateral thickness.

Example 12 includes the integrated circuit of any one of Examples 1-11, wherein the ends of the first and second semiconductor bodies are offset from the outermost sidewall of the spacer structure by between 2 nm and 4 nm.

Example 13 is a printed circuit board that includes the integrated circuit of any one of Examples 1-12.

Example 14 is an electronic device that includes a chip package having one or more dies. At least one of the one or more dies includes a plurality of semiconductor nanoribbons extending lengthwise in a first direction between a first epitaxial region and a second epitaxial region with the plurality of semiconductor nanoribbons being over one another in a second direction, a gate structure around the plurality of semiconductor nanoribbons, and a spacer structure that extends in the second direction around ends of the semiconductor nanoribbons. The end of a given semiconductor nanoribbon is laterally offset from an outermost sidewall of an adjacent portion of the spacer structure.

Example 15 includes the electronic device of claim 14, wherein the plurality of semiconductor nanoribbons comprise germanium, silicon, or any combination thereof.

Example 16 includes the electronic device of claim 14 or 15, wherein the spacer structure is a first spacer structure on one side of the gate structure, and the at least one of the one or more dies further comprises a second spacer structure on an opposite side of the gate structure, the second spacer structure extending in the second direction around opposite ends of the semiconductor nanoribbons.

Example 17 includes the electronic device of claim 16, wherein the opposite ends of the semiconductor nanoribbons are laterally recessed from an outermost sidewall of the second spacer structure.

Example 18 includes the electronic device of any one of Examples 14-17, wherein the second direction is orthogonal to the first direction.

Example 19 includes the electronic device of any one of Examples 14-18, wherein the recessed ends of the semiconductor nanoribbons are substantially aligned along the second direction.

Example 20 includes the electronic device of any one of Examples 14-19, wherein portions of the first epitaxial region contact the ends of the semiconductor nanoribbons, such that the spacer structure extends in the second direction around the portions of the first epitaxial region.

Example 21 includes the electronic device of any one of Examples 14-20, wherein the spacer structure between adjacent ends of the semiconductor nanoribbons has a lateral thickness in the first direction of between about 5 nm and about 10 nm.

Example 22 includes the electronic device of any one of Examples 14-21, wherein the ends of the semiconductor nanoribbons are laterally inward from the outermost sidewall of the spacer structure by between about 2 nm and about 4 nm.

Example 23 includes the electronic device of any one of Examples 14-22, further comprising a printed circuit board, wherein the chip package is attached to the printed circuit board.

Example 24 is a method of forming an integrated circuit. The method includes forming a multilayer fin extending lengthwise in a first direction, the multilayer fin including first material layers alternating with second material layers, the second material layers comprising a semiconductor material suitable for use as a nanoribbon channel; forming a sacrificial layer and spacers on sidewalls of the sacrificial layer, the sacrificial layer and spacers extending over the multilayer fin in a second direction different form the first direction; removing portions of the multilayer fin not protected beneath the sacrificial layer and spacers; laterally etching exposed ends of the first material layers; forming an inner spacer around exposed ends of the second material layers; laterally etching the exposed ends of the second material layers, such that the ends of the second material layers are laterally inward from an outermost sidewall of the inner spacer; and growing an epitaxial material from the ends of the second material layers.

Example 25 includes the method of Example 24, wherein the first material layers comprise silicon and germanium and the second material layers comprise silicon.

Example 26 includes the method of Example 24 or 25, further comprising removing the first material layers.

Example 27 includes the method of any one of Examples 24-26, further comprising forming a gate structure around portions of the second material layers.

Example 28 includes the method of any one of Examples 24-27, wherein laterally etching the exposed ends of the first material layers comprises laterally etching the first material layers by between about 5 nm and about 10 nm.

Example 29 includes the method of any one of Examples 24-28, wherein laterally etching the exposed ends of the second material layers comprises laterally etching the second material layers be between about 2 nm and about 4 nm.

Example 30 is an integrated circuit that includes a plurality of semiconductor nanoribbons extending lengthwise in a first direction between a first epitaxial region and a second epitaxial region with the plurality of semiconductor nanoribbons being over one another in a second direction, a first spacer structure that extends in the second direction around first ends of the semiconductor nanoribbons adjacent to the first epitaxial region, a second spacer structure that extends in the second direction around second ends of the semiconductor nanoribbons adjacent to the second epitaxial region, and a gate structure around the plurality of semiconductor nanoribbons and between the first spacer structure and the second spacer structure. First portions of the first epitaxial region extend laterally in the first direction within the first spacer structure to contact the first ends of the semiconductor nanoribbons, and second portions of the second epitaxial region extend laterally in a third direction opposite to the first direction within the second spacer structure to contact the second ends of the semiconductor nanoribbons.

Example 31 includes the integrated circuit of Example 30, wherein the first portions of the first epitaxial region and the second portions of the second epitaxial region are aligned across from another in the first direction.

Example 32 includes the integrated circuit of Example 30 or 31, wherein the plurality of semiconductor nanoribbons comprise germanium, silicon, or any combination thereof.

Example 33 includes the integrated circuit of any one of Examples 30-32, wherein the first ends of the semiconductor nanoribbons are laterally recessed from an outermost sidewall of the first spacer structure, and the second ends of the semiconductor nanoribbons are laterally recessed from an outermost sidewall of the second spacer structure.

Example 34 includes the integrated circuit of any one of Examples 30-33, wherein the second direction is orthogonal to the first direction.

Example 35 includes the integrated circuit of any one of Examples 30-34, wherein the first spacer structure between adjacent first ends of the semiconductor nanoribbons has a lateral thickness in the first direction of between about 5 nm and about 10 nm and the second spacer structure between adjacent second ends of the semiconductor nanoribbons has a lateral thickness in the first direction of between about 5 nm and about 10 nm.

Example 36 includes the integrated circuit of any one of Examples 30-35, wherein the first portions of the first epitaxial region extend laterally in the first direction within the first spacer structure by between about 2 nm and about 4 nm and the second portions of the second epitaxial region extend laterally in the first direction within the second spacer structure by between about 2 nm and about 4 nm.

Example 37 is a printed circuit board that includes the integrated circuit of any one of Examples 30-36.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor body and a second semiconductor body each extending lengthwise in a first direction between a first epitaxial region and a second epitaxial region, the first semiconductor body over the second semiconductor body in a second direction;
a gate structure at least partially around the first and second semiconductor bodies; and
a spacer structure that extends in the second direction around ends of the first and second semiconductor bodies, wherein the end sidewall of a given semiconductor body is laterally inward of an outermost sidewall of an adjacent portion of the spacer structure.

2. The integrated circuit of claim 1, wherein the first and second semiconductor bodies are nanoribbons that comprise germanium, silicon, or any combination thereof.

3. The integrated circuit of claim 1, wherein at least one of the first or second epitaxial regions has a protruding portion and an indented portion, the protruding portion laterally extending toward the gate structure and between upper and lower portions of the spacer structure, and the indented portion having a portion of the spacer structure extending therein.

4. The integrated circuit of claim 1, wherein the spacer structure is a first spacer structure on one side of the gate structure, and the integrated circuit further comprises a second spacer structure on an opposite side of the gate structure, the second spacer structure extending in the second direction around opposite ends of the first and second semiconductor bodies.

5. The integrated circuit of claim 1, wherein portions of the first epitaxial region contact the ends of the first and second semiconductor bodies, such that the spacer structure extends in the second direction around the portions of the first epitaxial region.

6. The integrated circuit of claim 1, wherein the spacer structure between adjacent ends of the first and second semiconductor bodies has a lateral thickness in the first direction of between 5 nm and 10 nm.

7. The integrated circuit of claim 1, wherein the ends of the first and second semiconductor bodies are offset from the outermost sidewall of the spacer structure by between 2 nm and 4 nm.

8. A printed circuit board comprising the integrated circuit of claim 1.

9. An electronic device, comprising:
a chip package comprising one or more dies, at least one of the one or more dies comprising
a plurality of semiconductor nanoribbons extending lengthwise in a first direction between a first epitaxial region and a second epitaxial region;
a gate structure around the plurality of semiconductor nanoribbons, the plurality of semiconductor nanoribbons being over one another in a second direction; and
a spacer structure that extends in the second direction around ends of the semiconductor nanoribbons, wherein the end of a given semiconductor nanoribbon is laterally offset from an outermost sidewall of an adjacent portion of the spacer structure.

10. The electronic device of claim 9, wherein the spacer structure is a first spacer structure on one side of the gate structure, and the at least one of the one or more dies further comprises a second spacer structure on an opposite side of the gate structure, the second spacer structure extending in the second direction around opposite ends of the semiconductor nanoribbons.

11. The electronic device of claim 10, wherein the opposite ends of the semiconductor nanoribbons are laterally recessed from an outermost sidewall of the second spacer structure.

12. The electronic device of claim 9, wherein the recessed ends of the semiconductor nanoribbons are substantially aligned along the second direction.

13. The electronic device of claim 9, wherein portions of the first epitaxial region contact the ends of the semiconductor nanoribbons, such that the spacer structure extends in the second direction around the portions of the first epitaxial region.

14. The electronic device of claim 9, further comprising a printed circuit board, wherein the chip package is attached to the printed circuit board.

15. An integrated circuit comprising:
a plurality of semiconductor nanoribbons extending lengthwise in a first direction between a first epitaxial region and a second epitaxial region, the plurality of semiconductor nanoribbons being over one another in a second direction;
a first spacer structure that extends in the second direction around first ends of the semiconductor nanoribbons adjacent to the first epitaxial region;
a second spacer structure that extends in the second direction around second ends of the semiconductor nanoribbons adjacent to the second epitaxial region; and
a gate structure around the plurality of semiconductor nanoribbons and between the first spacer structure and the second spacer structure;
wherein first portions of the first epitaxial region extend laterally in the first direction within the first spacer structure to contact the first ends of the semiconductor nanoribbons, and second portions of the second epitaxial region extend laterally in a third direction opposite to the first direction within the second spacer structure to contact the second ends of the semiconductor nanoribbons.

16. The integrated circuit of claim 15, wherein the first portions of the first epitaxial region and the second portions of the second epitaxial region are aligned across from another in the first direction.

17. The integrated circuit of claim 15, wherein the first ends of the semiconductor nanoribbons are laterally recessed from an outermost sidewall of the first spacer structure, and the second ends of the semiconductor nanoribbons are laterally recessed from an outermost sidewall of the second spacer structure.

18. The integrated circuit of claim 15, wherein the first spacer structure between adjacent first ends of the semiconductor nanoribbons has a lateral thickness in the first direction of between about 5 nm and about 10 nm and the second spacer structure between adjacent second ends of the semiconductor nanoribbons has a lateral thickness in the first direction of between about 5 nm and about 10 nm.

19. The integrated circuit of claim 15, wherein the first portions of the first epitaxial region extend laterally in the first direction within the first spacer structure by between about 2 nm and about 4 nm and the second portions of the second epitaxial region extend laterally in the first direction within the second spacer structure by between about 2 nm and about 4 nm.

20. A printed circuit board comprising the integrated circuit of claim 15.
